(19) United States
(12) Patent Application Publication
(10) Pub. No.: US 2026/0206642 A1
(43) Pub. Date: Jul. 16, 2026

(54) ISOLATING TRANSISTOR HALF-BRIDGE PACKAGE

(71) Applicants: Toyota Motor Engineering & Manufacturing North America, Inc., Plano, TX (US); Virginia Tech Intellectual Properties, Inc., Blacksburg, VA (US)

(72) Inventors: Matthias Spieler, Blacksburg, VA (US); Rolando P. Burgos, Blacksburg, VA (US); Dong Dong, Blacksburg, VA (US); Feng Zhou, Ann Arbor, MI (US)

(73) Assignees: Toyota Motor Engineering & Manufacturing North America, Inc., Plano, TX (US); Virginia Tech Intellectual Properties, Inc., Blacksburg, VA (US)

(21) Appl. No.: 19/015,934

(22) Filed: Jan. 10, 2025

(51) Int. Cl. H01L 25/07; H01L 23/373; H01L 23/538

(52) U.S. Cl. CPC H10W 90/00; H10W 40/255; H10W 70/60; H10W 70/611

(57) ABSTRACT

Various arrangements described herein relate to an improved package design for power electronics. In one embodiment, a die package is disclosed. The die package includes a substrate. The substrate including a top-side copper trace, including a cutout. The substrate further includes a bottom-side copper trace. The substrate also includes a ceramic layer sandwiched between the top-side copper trace and the bottom-side copper trace. The die package includes a die mounted within the cutout to the top-side copper trace.

### TECHNICAL FIELD

The subject matter described herein relates, in general, to transistors within a half-bridge circuit, and, in particular, to a compact package design for the transistors in which the transistors are integrated on a single PCB together.

### BACKGROUND

Power electronics, such as inverters, are essential components in many modern electronic systems, particularly in applications such as electric vehicles, renewable energy systems, and other such systems. These devices typically utilize semiconductor devices arranged in various circuit topologies to convert direct current (dc) to alternating current (ac). For example, these devices may implement circuits with a half-bridge topology, which includes two switching devices per phase that alternately conduct to generate the desired ac output. The half-bridge topology, though effective, poses several design challenges, particularly in terms of compactness, electrical performance, and thermal management.

The integration of the half-bridge circuit into a die package influences both electrical and thermal characteristics. In some implementations, die packages exhibit significant limitations in these areas. For example, the physical layout can lead to a suboptimal power density, requiring more area for operation, which can be a drawback in applications with limited space. Additionally, the electrical characteristics, such as switching efficiency and power loss, are often affected by the parasitic inductance, capacitance, and resistance inherent in the packaging design. These parasitic elements can increase switching times, generate unwanted electromagnetic interference (EMI), and reduce the overall efficiency of the device.

Thermal management is another issue in inverter designs. During operation, power semiconductor devices, such as metal-oxide-semiconductor field-effect transistors (MOSFETs), generate substantial power loss, resulting in heat and temperature increase of the die. Effective dissipation of this heat ensures reliable operation and prevents thermal runaway. Various package designs may fail to provide sufficient heat dissipation, resulting in the need for additional cooling mechanisms that increase system size, cost, and complexity. There is a need for an improved die package design that addresses the noted shortcomings, specifically by enhancing electrical performance, reducing parasitic elements, and improving thermal management in a more compact and efficient form factor. An optimized die package could enable higher switching speeds, reduced energy losses, and improved reliability while also providing a more compact solution for integration into modern power inverter systems.

### SUMMARY

Various embodiments relate to an improved package design for power electronics. As noted previously, the package design for various devices, such as inverters implementing a half-bridge topology, may suffer from difficulties relating to compactness, electrical performance, and thermal management. That is, for example, less compact designs may require more complex connection routing, thereby increasing the likelihood of unwanted electrical characteristics, such as parasitic capacitance and/or inductance. Moreover, the larger footprint of such designs can complicate placement within a larger/power dense system.

Therefore, in one arrangement, an improved die package is provided in which a half-bridge circuit or another circuit design may be implemented. The package is generally formed using a directed bonded copper (DBC) ceramic substrate or another substrate (e.g., an organic substrate). A top side of a ceramic layer includes a top-side copper trace with cutouts for separate dies. A bottom side of the ceramic includes a bottom-side copper trace. Thus, the ceramic is sandwiched between the top-side copper trace and the bottom-side copper trace. In general, the bottom-side copper trace functions to dissipate heat via thermal stitching over subsequent layers extending beyond the bottom-side copper trace and connecting with, for example, a heatsink. The top-side copper trace includes the cutouts where the dies can be sintered or soldered flush within the top-side copper trace layer. The top-side copper trace itself can serve as the drain connection for the dies, while other electrical connections are formed using vias through top-side layers.

The dies may be MOSFETs for a high side and a low side of an inverter. By integrating the dies on a common substrate, the spacing between the dies can be reduced, thereby providing a higher power density. Depending on the implementation, the design may include two, four, six, or more MOSFET dies. Moreover, the dies can be provided as pairs on common substrates or all on a single substrate that is embedded with a PCB. This integration provides for the higher densities that ultimately improve the various characteristics of the package, including compactness, parasitic inductance and capacitance, electromagnetic interference, thermal properties, etc.

In one embodiment, a die package is disclosed. The die package includes a substrate. The substrate including a top-side copper trace, including a cutout. The substrate further includes a bottom-side copper trace. The substrate also includes a ceramic layer sandwiched between the top-side copper trace and the bottom-side copper trace. The die package includes a die mounted within the cutout to the top-side copper trace.

In another embodiment, a device is disclosed. The device includes a top-side copper trace, including a first cutout and a second cutout. The device includes a bottom-side copper trace. The device includes a separator layer sandwiched between the top-side copper trace and the bottom-side copper trace. The device includes a first die mounted within the first cutout and a second die mounted within the second cutout to the top-side copper trace.

In one embodiment, an apparatus is disclosed. The apparatus includes a top-side copper trace, including multiple cutouts. The top-side copper trace providing an electrical connection to a drain using vias within layers above the top-side copper trace. The device includes a bottom-side copper trace that is substantially planar and substantially continuous along a bottom of a ceramic layer. The bottom-side copper trace provides thermal stitching to a heatsink using layers of vias between the bottom-side copper trace and the heatsink. The device includes the ceramic layer sandwiched between the top-side copper trace and the bottom-side copper trace. The ceramic layer functioning as a separator between the top-side copper trace and the bottom-side copper trace. The device includes dies mounted within the multiple cutouts of the top-side copper trace.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates one example of a die package and a PCB, including multiple die packages.

FIG. 2 illustrates two separate examples of PCBs that include discrete die packages.

FIG. 3 illustrates one embodiment of an improved die package that includes multiple dies on a single substrate.

FIG. 4 illustrates top and side views of an improved die package.

FIG. 5 illustrates a top view of an improved die package.

FIG. 6 illustrates a cutaway side view of an improved die package.

FIG. 7 is a diagram comparing two separate PCBs with different arrangements of dies.

FIG. 8 illustrates separate circuit diagrams for circuits that may be implemented with the improved package design.

FIG. 9 is a flowchart illustrating one approach for providing an improved package design.

### DETAILED DESCRIPTION

Various embodiments of an improved package design for power electronics are disclosed herein. As noted previously, the package design for various devices, such as inverters implementing a half-bridge topology, may suffer from difficulties relating to compactness, electrical performance, and thermal management. That is, for example, less compact designs may require more complex connection routing, thereby increasing the likelihood of unwanted electrical characteristics, such as parasitic capacitance and/or inductance. Moreover, the larger footprint of such designs can complicate placement within a larger system and may also not optimize thermal dissipation.

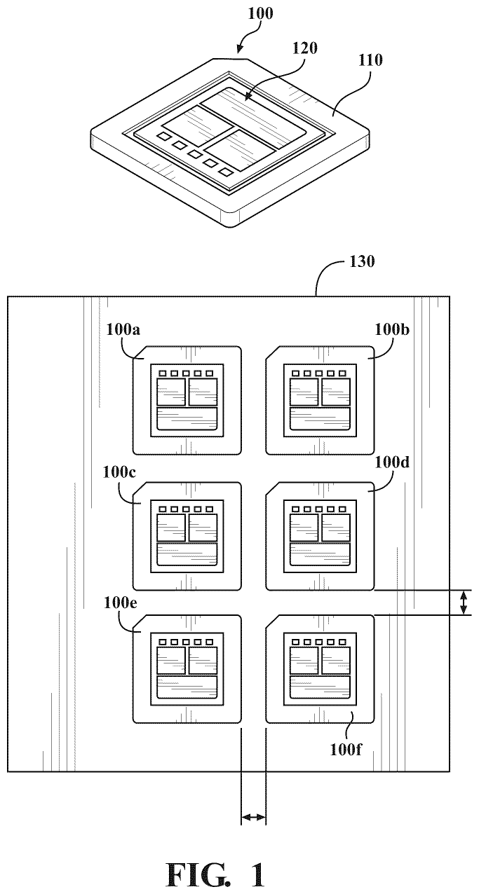

By way of example, consider FIG. 1, which illustrates a power electronics device 100. As shown, a discrete substrate 110 includes a single die 120, which may be a MOSFET or another electronic device or combination of devices arranged into a circuit. One example of an embedded PCB inverter 130 is shown that includes multiple discrete power electronics devices 100a-f arranged in a two-by-three configuration. Because of fabrication constraints, the device 100a-f is fabricated in a way that maintains a minimum distance (e.g., 2.0-4 mm) between the devices. The distance functions to limit the minimum footprint for the devices 100a-f when embedded on the printed circuit board (PCB).

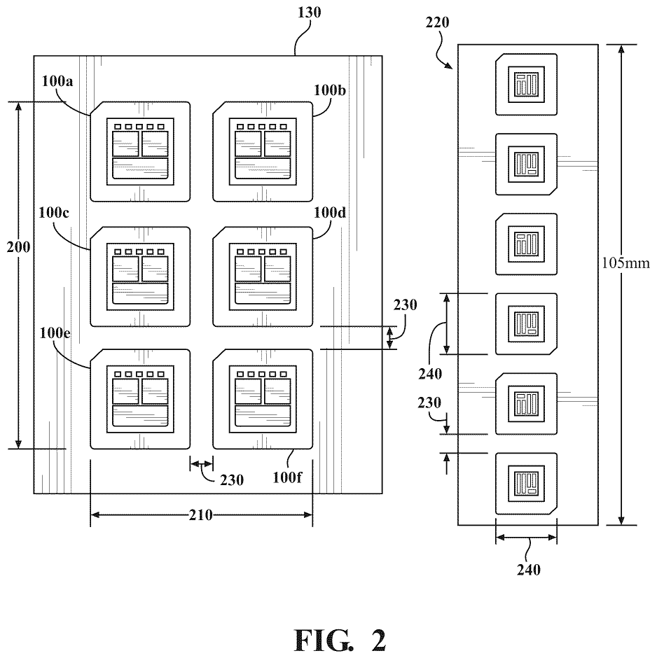

FIG. 2 illustrates a further depiction of the inverter 130 from FIG. 1 in which a footprint of the devices 100a-f is further identified. As shown, the minimum footprint is a height 200 by a width 210. In one example, the area of the device 130 to be about 1683 mm². FIG. 2 also illustrates an additional layout 220 of the device 130. In this arrangement, all of the devices 100a-f are lined up in a row. This arrangement can reduce the footprint to roughly 1575 mm². However, the layout 220 is still constrained by the inter-substrate separation 230 (e.g., 2-4.0 mm) for the devices 100a-f with width 240.

Therefore, in one arrangement, an improved die package is provided in which a half-bridge circuit or another circuit may be implemented for a more compact power electronics system with lower system loss. The package is generally formed using a directed bonded copper (DBC) substrate that may be ceramic or an organic substrate. A top side of a ceramic layer includes a top-side copper trace with cutouts for separate dies. A bottom side of the ceramic includes a bottom-side copper trace. Thus, the ceramic is sandwiched between the top-side copper trace and the bottom-side copper trace. In general, the bottom-side copper trace functions to dissipate heat via thermal stitching over subsequent layers extending beyond the bottom-side copper trace and connecting with, for example, a heatsink. The top-side copper trace includes the cutouts where the dies can be sintered or soldered flush within the top-side copper trace layer. The top-side copper trace itself can serve as the drain connection for the dies while other electrical connections are formed using vias through top-side layers.

The dies may be MOSFETs for a high side and a low side of an inverter. In an alternative arrangement, the dies may be Insulated-Gate Bipolar Transistor (IGBT). By integrating the dies on a common substrate, the spacing between the dies can be reduced, thereby providing a higher power density. Depending on the implementation, the design may include two, four, six, or more MOSFET dies. Moreover, the dies can be provided as pairs on common substrates or all on a single substrate that is embedded with a PCB. This integration provides for the higher densities that ultimately improve the various characteristics of package, including compactness, parasitic inductance and capacitance, electromagnetic interference, thermal properties, etc.

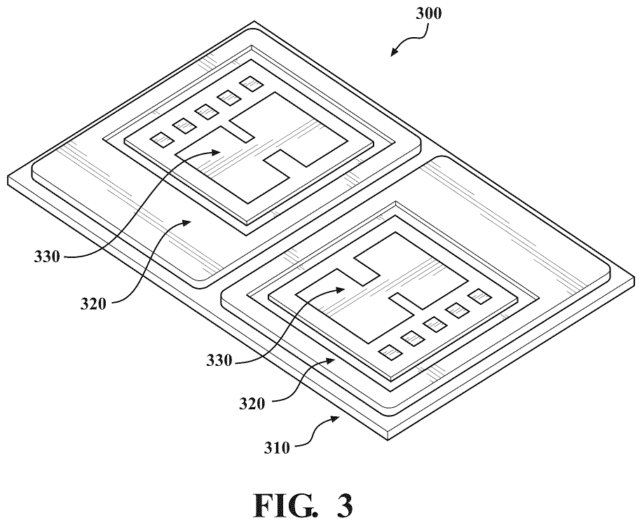

With reference to FIG. 3, one example of an integrated package 300 with improved power density is illustrated. The package 300 includes a substrate 310 that is, for example, a direct-bonded copper (DBC) ceramic substrate. The substrate may also be an organic substrate, such as VT-4B7, HENKEL HT-07006, RISHO 7210N, or DUPONT ODBC TEMPRION™). In the example of FIG. 3, the substrate 310 includes copper traces 320 mounted/bonded to a top-side surface of the substrate 310. It should be appreciated that while the positioning of various elements may be referred to using relative phrasing (e.g., top-side, bottom-side), these relative terms are simply used for purposes of this description and should not be construed as limiting the way in which the elements can be positioned. That is, the term “top” generally refers to a +z direction out of the surface of the drawing while the term “bottom” generally refers to a −z direction into the surface of the drawing in order to facilitate description relative to a defined point of reference. However, in practice, the device may be flipped or rotated relative to the defined point of reference without changing a configuration of the device itself.

Continuing with FIG. 3, the copper traces 320 are in the shape of a polygon (e.g., rectangle) and are attached to the ceramic by, for example, a copper-oxygen eutectic bonding process or another attachment method. Similarly, a bottom-side copper trace (not shown) is attached opposite to the traces 320 on the substrate 310 and may be attached in a similar manner. The top-side copper traces 320 are formed in the shape of a polygon and may be generally rectangular in at least one approach. In any case, the copper traces 320 each include a cutout within which respective dies 330 are attached. The cutout may be the height of the dies 330 and the height of the bond line, such that the dies then sit flush to an upper surface of the copper traces 320 when mounted. The dies themselves are, for example, MOSFETs that are sintered or soldered to the copper traces 320. In one or more arrangements, the dies 330 may undergo a pre-attachment treatment that applies copper plating to the dies 330. In further arrangements, the plating may be aluminum.

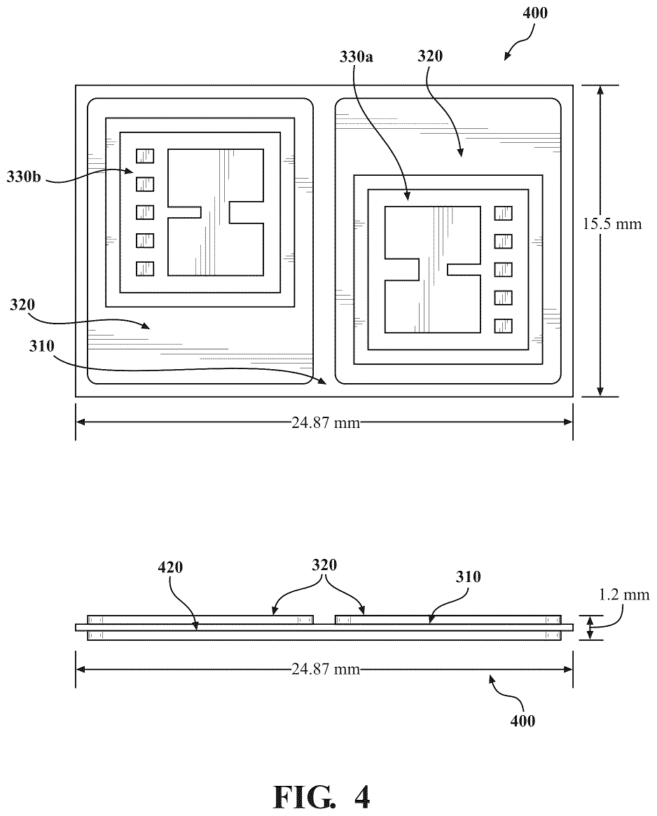

FIG. 4 illustrates additional views of the package 300 of FIG. 3. In particular, FIG. 4 illustrates a top-down view 400 and a side view 410. The top view 400 shows how the separate copper traces 320 are positioned in close proximity on the substrate 310 to improve the footprint of the dies. The top-down view 400 further shows the low-side MOSFET 330a and the high-side MOSFET 330b associated with a half-bridge configuration. Moreover, the overall dimensions for the substrate are shown as 15.5 mm by 24.87 mm. The side view 410 illustrates the arrangement of the top-side copper traces 320 relative to a bottom-side copper trace 420. In general, the bottom-side copper trace 420 functions as a diffuser for spreading thermal energy from the dies 330. Additionally, FIG. 4 also shows how the cutout of the copper traces 320 functions to embed the dies 330 flush within the cutouts. Embedding the dies 330 flush within the cutouts maintains the dies 330 within the same layer as the copper traces 320, thereby facilitating the integration of the package 300 with further layers that support, for example, electrical and thermal connections with the dies 330.

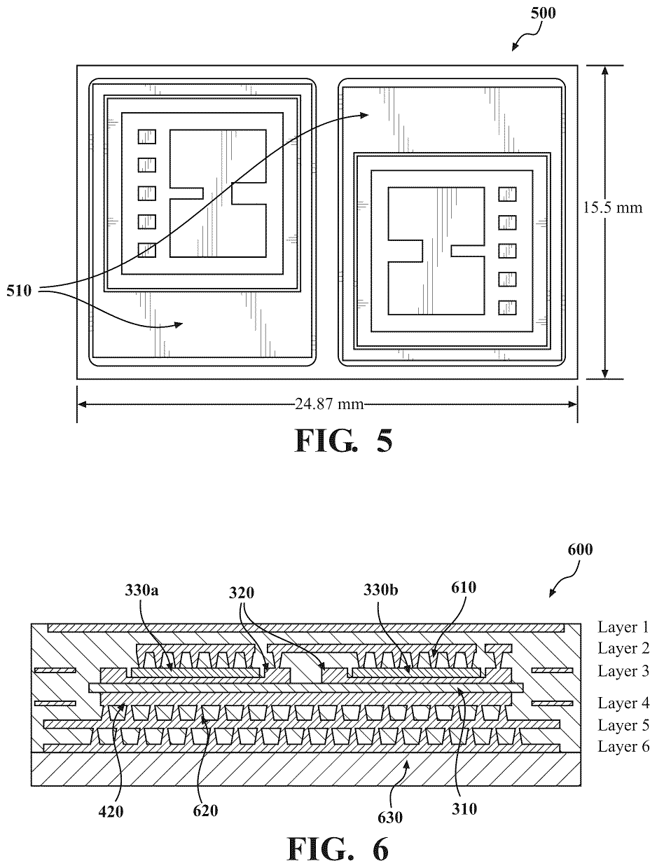

FIG. 5 illustrates an additional top view 500 of the package 300. In FIG. 5, areas 510 highlight placement for electrical connections with respective top-side copper traces. This shows where vias are placed by using laser drilling during the fabrication process. In general, connections with the copper traces and the dies are made with laser-drilled vias. Moreover, the bottom-side copper trace, in one approach, can be on the low-voltage ground potential and is connected using vias to a heat sink.

As further explanation of the overall package design, as can be embedded with a printed circuit board (PCB), consider FIG. 6. FIG. 6 illustrates a side-cutaway view 600 of the package with additional layers added for integrating electrical and thermal connections. For example, the view 600 shows six layers as part of the completed package in addition to the ceramic substrate 310. In further examples, the package may include eight or more while in other embodiments the package may include fewer layers with an even distribution between a top side and a bottom side. In any case, the view 600 illustrates how the traces 320 are milled out to accommodate the dies 330a and 330b. Additionally, the view includes representations of laser-drilled vias 610 for the top side that provide for connecting the dies 330a/b and the copper traces 320. Additionally, the vias 620 on the bottom side thermally connect the bottom-side copper trace 420 with the heat sink 630 to dissipate heat generated by the dies 330. In this way, the package 300 is able to improve the power density through integration of the dies 330 on the same substrate, thereby providing for a reduced footprint.

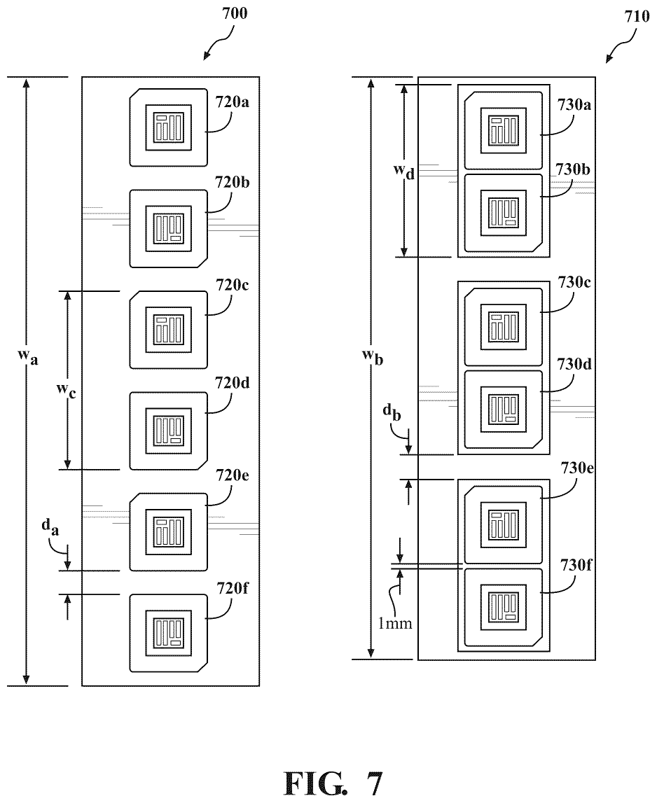

FIG. 7 illustrates an example of implementing the die package 300 on a PCB versus discrete dies. As shown, FIG. 7 includes a discrete PCB 700 and an integrated PCB 710. The discrete PCB 700 includes six discrete dies 720a-f that are all separately formed on discrete substrates and embedded on the PCB 700. By contrast, high-side and low-side MOSFETs on dies 730a-f are paired together on common substrates in the integrated PCB 710. The clearance between the dies 730a-f is decreased with the integrated PCB 710 to 1.0 mm, which is smaller than the distance dₐ between the discrete dies 720a-f. Thus, the width w_{d} is smaller than the width w_{c} since fabrication limitations prevent w_{c} from being reduced in the discrete PCB 700. The distance between the discrete transistors dₐ equals the distance d_{b} between the half-bridges of the separate substrates of the integrated PCB 710. The total PCB width w_{b} of the integrated PCB 710 is thus smaller than the total PCB width wₐ of the discrete PCB 700. Thus, the power density of the integrated PCB 710 is improved over the PCB 700. It should be noted that in further arrangements, the pairs of half-bridges 730a-f may be integrated onto a single substrate instead of three separate substrates, thereby further improving the power density.

TABLE 1

| | | |
|---|---|---|
| Parameter | PCB 700 | PCB 710 |

| | | |
|---|---|---|
| Die Integration | Discrete | Half-bridge |

| | | | | |
|---|---|---|---|---|
| Half-bridge size | 410.7 | mm² | 385.5 | mm² |
| L_{PCB} | 2.416 | nH | 1.966 | nH |
| C_{DS:LS} | 50.3 | pF | 47.3 | pF |
| C_{DS:HS} | 30.2 | pF | 24.7 | pF |

In any case, Table 1 illustrates some attributes of the discrete PCB 700 in comparison to the integrated PCB 710. Accordingly, the integrated PCB 710 utilizes the high integration of the half-bridge power stage to reduce the footprint (i.e., total area), decrease the drain-source parasitic capacitance, and enable a small current commutation loop design while achieving a high thermal conductivity to dissipate thermal energy efficiently.

While a comparison between PCB 700 and PCB 710 is generally described, it should be noted that these PCBs have a six-layer design. However, the integrated PCB 710 may also be implemented with an eight-layer design that further optimizes a commutation loop through vertical integration. That is, due to a smaller distance between the high-side and low-side dies of the integrated PCB 710, the trace length is decreased. As a result, the PCB 710 includes a small current commutation loop than the six-layer discrete PCB 700. Overall, the discrete PCB 700 has a larger trace overlap area than the PCB 710, resulting in increases in parasitic capacitance. The increase in parasitic capacitance further increases switching loss and EMI.

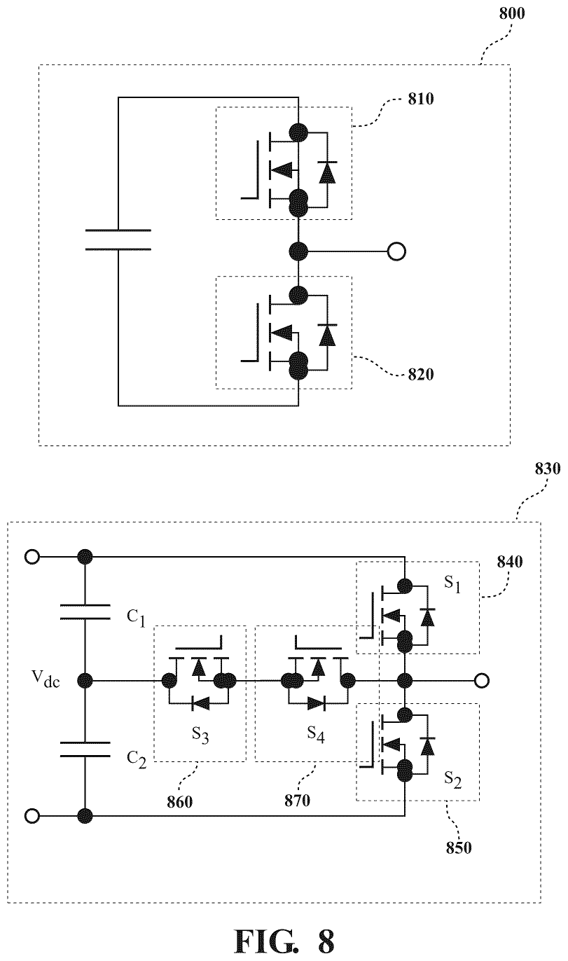

Turning to FIG. 8, two separate examples of circuits that can be implemented using the present approach are illustrated. For example, circuit 800 is a half-bridge circuit with a high-side MOSFET 810 and a low-side MOSFET 820 arranged on the same substrate. Other components and connections may be located on the same PCB but are generally not formed on the same dies. The circuit 830 is a three-level t-type converter that includes MOSFETs 840-870. The separate MOSFETs 840-870 can be arranged as pairs on two separate substrates or may be integrated as four MOSFET dies on a single substrate. Thus, the noted technique of integrating multiple dies on a single substrate can be used with additional circuit designs beyond a half-bridge configuration.

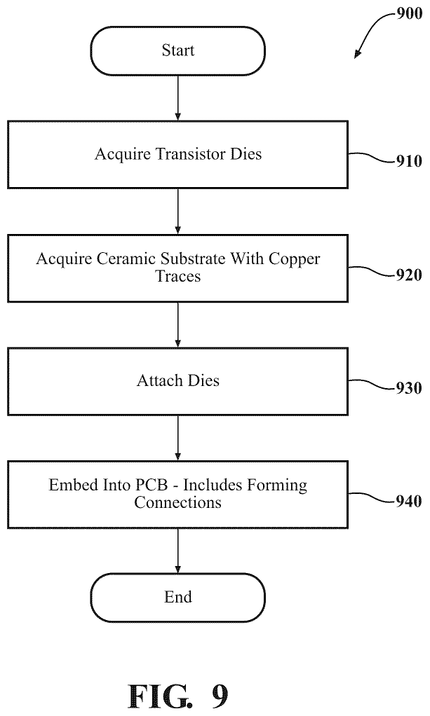

With reference to FIG. 9, one embodiment of a method 900 is illustrated in the form of a flowchart. The method 900 is associated with fabricating an integrated PCB device. For example, the method 900 may be used in association with the fabrication of the die package 300 of FIG. 3. In general, the method 900 is implemented by a system for PCB fabrication that may include a single device or a combination of different devices.

At 910, the system acquires transistor dies. The transistor dies are, for example, fabricated according to an integrated circuit fabrication process that may include front-end-of-line (FEOL) processes, including wafer preparation, trench isolation, well formation, gate module formation, source and drain formation, and so on. In general, the transistor dies are MOSFETs that are arranged in a particular configuration to accommodate a particular circuit design, e.g., an inverter utilizing a half-bridge design.

At 920, the system acquires a ceramic substrate with direct bonded copper traces that separately include cutouts for the MOSFETs. That is, the system bonds the copper traces to the ceramic according to the particular design. The design may include two copper traces per substrate, four copper traces per substrate, six copper traces per substrate, or more. In any case, an arrangement of six copper traces (i.e., copper trace polygons) that are discrete polygons can be mounted to the same substrate in, for example, a three-phase inverter design using a separate half-bridge for each phase. Moreover, the system may mill out the cutout within each polygon to accommodate a respective one of the dies. Alternatively, the dies may be mounted using standoffs. In addition to the top-side copper trace, the ceramic substrate also includes a bottom-side copper trace opposite the top-side copper trace. In general, the bottom-side copper trace may be a single polygon that spans a bottom surface of the substrate and that generally acts to dissipate heat from the dies. In further arrangements, the bottom-side copper trace may mirror the top-side copper trace providing a symmetrical polygon layout to facilitate reducing mechanical stresses.

At 930, the system attaches the dies to the copper traces. In one example, the system sinters the dies. In further examples, the system may glue the dies or solder the dies or sinter the dies onto the copper traces. In general, the dies are attached within the cutouts such that the dies sit flush with a top side of the copper traces in order to integrate the dies within the same layer.

At 940, the system embeds the package into the PCB. As part of embedding the package, the system may form various electrical and/or thermal connections. For example, the system can form laser-drilled vias with separately deposited layers on the top side and the bottom side. The layers are generally evenly distributed on each side and can range from three layers on each side to four layers or more. In any case, the system forms the top-side layers with via connections for various electrical connections, such as a drain connection, and other electrical connections with the dies to form the inverter in the half-bridge implementation. Separately, the system forms the via connections on the bottom-side to thermally link the bottom-side copper trace with, for example, a heat sink in order to provide for dissipating heat from the device.

Detailed embodiments are disclosed herein. However, it is to be understood that the disclosed embodiments are intended only as examples. Therefore, specific structural and functional details disclosed herein are not to be interpreted as limiting but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-9, but the embodiments are not limited to the illustrated structure or application.

The flowcharts and block diagrams in the Figures illustrate the architecture, functionality, and operation of possible implementations of systems, methods, and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein. The systems, components and/or processes also can be embedded in a computer-readable storage, such as a computer program product or other data programs storage device, readable by a machine, tangibly embodying a program of instructions executable by the machine to perform methods and processes described herein. These elements also can be embedded in an application product that comprises all the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a read-only memory (ROM), an erasable programmable read-only memory (EPROM or Flash memory), a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain, or store a program for use by or in connection with an instruction execution system, apparatus, or device.

Generally, module, as used herein, includes routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an application-specific integrated circuit (ASIC), a hardware component of a system on a chip (SoC), as a programmable logic array (PLA), or as another suitable hardware component that is embedded with a defined configuration set (e.g., instructions) for performing the disclosed functions. The term “operatively connected” and “communicatively coupled,” as used throughout this description, can include direct or indirect connections, including connections without direct physical contact.

Program code embodied on a computer-readable medium may be transmitted using any appropriate medium, including but not limited to wireless, wireline, optical fiber, cable, RF, etc., or any suitable combination of the foregoing. Computer program code for carrying out operations for aspects of the present arrangements may be written in any combination of one or more programming languages, including an object-oriented programming language such as Java™ Smalltalk, C++ or the like and conventional procedural programming languages, such as the “C” programming language or similar programming languages. The program code may execute entirely on the user's computer, partly on the user's computer, as a standalone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g., AB, AC, BC or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. A die package, comprising:
a substrate comprised of:
i. a top-side copper trace, including a cutout,
ii. a bottom-side copper trace, and
iii. a ceramic layer sandwiched between the top-side copper trace and the bottom-side copper trace; and
a die mounted within the cutout to the top-side copper trace.

2. The die package of claim 1, wherein the cutout is one of multiple cutouts within the top-side copper trace that is separated into discrete traces per cutout, and wherein the multiple cutouts include separate dies, including the die.

3. The die package of claim 2, wherein the separate dies are metal-oxide-semiconductor field-effect transistors (MOSFETs) or Insulated-Gate Bipolar Transistor (IGBT) arranged in at least one half-bridge configuration as part of an inverter within a power electronics device, and
wherein the MOSFETs are high-side and low-side MOSFETs within the half-bridge configuration.

4. The die package of claim 2, wherein the substrate is continuous to support the separate dies together embedded within a single printed circuit board (PCB).

5. The die package of claim 4, wherein the multiple cutouts with the separate dies are spaced with about a 1.0 mm separation that reduces a footprint of the die package such that the separate dies are integrated together on the single PCB.

6. The die package of claim 1, wherein the top-side copper trace provides an electrical connection to a drain using vias within layers above the top-side copper trace, and
wherein electrical connections for inputs, outputs, and controlling the die are routed through the layers above the top-side copper trace.

7. The die package of claim 1, wherein the ceramic layer functions as a separator between the top-side copper trace and the bottom-side copper trace.

8. The die package of claim 1, wherein the bottom-side copper trace provides thermal stitching to a heatsink using layers of vias between the bottom-side copper trace and the heatsink.

9. A device, comprising:
a top-side copper trace, including a first cutout and a second cutout;
a bottom-side copper trace;
a separator layer sandwiched between the top-side copper trace and the bottom-side copper trace; and
a first die mounted within the first cutout and a second die mounted within the second cutout to the top-side copper trace.

10. The device of claim 9, wherein the first die and the second die are metal-oxide-semiconductor field-effect transistors (MOSFETs) arranged in a half-bridge configuration as part of an inverter within a power electronics device, and
wherein the MOSFETs are high-side and low-side MOSFETs within the half-bridge configuration.

11. The device of claim 9, wherein the separator layer is continuous to support the first die and the second die together embedded within a single printed circuit board (PCB).

12. The device of claim 9, wherein the first cutout and the second cutout are spaced with about a 1.0 mm separation that reduces a footprint of the device such that the first die and the second die are integrated together on the single PCB.

13. The device of claim 9, wherein the top-side copper trace provides an electrical connection to a drain using vias within layers above the top-side copper trace, and
wherein electrical connections for inputs, outputs, and controlling the die are routed through the layers above the top-side copper trace.

14. The device of claim 9, wherein the separator layer functions as a separator between the top-side copper trace and the bottom-side copper trace and is formed from one of: a ceramic material or an organic material.

15. The device of claim 9, wherein the bottom-side copper trace provides thermal stitching to a heatsink using layers of vias between the bottom-side copper trace and the heatsink.

16. An apparatus, comprising:
a top-side copper trace, including multiple cutouts, the top-side copper trace providing an electrical connection to a drain using vias within layers above the top-side copper trace;
a bottom-side copper trace that is substantially planar and substantially continuous along a bottom of a separator layer, the bottom-side copper trace provides thermal stitching to a heatsink using layers of vias between the bottom-side copper trace and the heatsink;
the separator layer sandwiched between the top-side copper trace and the bottom-side copper trace, the separator layer functioning as a separator between the top-side copper trace and the bottom-side copper trace; and
dies mounted within the multiple cutouts of the top-side copper trace.

17. The apparatus of claim 16, wherein the top-side copper trace is separated into discrete polygons on the separator layer per respective ones of the dies, the separator layer being a ceramic substrate or an organic substrate.

18. The apparatus of claim 16, wherein the dies are metal-oxide-semiconductor field-effect transistors (MOSFETs) arranged in at least one half-bridge configuration as part of an inverter within a power electronics device, and
wherein the MOSFETs are high-side and low-side MOSFETs within the half-bridge configuration.

19. The apparatus of claim 16, wherein the separator layer is continuous to support the separate dies together embedded within a single printed circuit board (PCB).

20. The apparatus of claim 19, wherein the multiple cutouts with the dies are spaced with about a 1.0 mm separation that reduces a footprint of the apparatus such that the dies are integrated together on the single PCB.
